(19) United States
(12) Patent Application Publication
(10) Pub. No.: US 2021/0218226 A1
(43) Pub. Date: Jul. 15, 2021

(54) LASER WAVELENGTH CONTROL DEVICE AND METHOD FOR CONTROLLING LASER WAVELENGTH

(71) Applicant: FUJITSU LIMITED, Kawasaki-shi (JP)

(72) Inventors: Takashi Kanda, Kawasaki (JP); Shingo Yamaguchi, Kawasaki (JP); Tetsuro Yamada, Kawasaki (JP)

(73) Assignee: FUJITSU LIMITED, Kawasaki-shi (JP)

(21) Appl. No.: 17/089,973

(22) Filed: Nov. 5, 2020

(30) Foreign Application Priority Data
Jan. 9, 2020 (JP) 2020-002018

(51) Int. Cl. H01S 5/06; H01S 5/0687

(52) U.S. Cl. CPC H01S 5/0612; H01S 5/0687; H01S 5/0617

(57) ABSTRACT

A laser wavelength control device, includes a memory; and a processor coupled to the memory and configured to: measure a wavelength of a laser beam emitted by a light source, when the measured wavelength is not in a target wavelength band, adjust a voltage to be applied to the light source such that a wavelength of the laser beam falls within the target wavelength band, and when a wavelength measured after the adjustment of the voltage is not in the target wavelength band, adjust a temperature of the light source such that the wavelength of the laser beam falls within the target wavelength band.

### CROSS-REFERENCE TO RELATED APPUCATION

This application is based upon and claims the benefit of priority of the prior Japanese Patent Application No. 2020-2018, filed on Jan. 9, 2020, the entire contents of which are incorporated herein by reference.

### FIELD

The embodiments discussed herein are related to a laser wavelength control device and a method for controlling a laser wavelength.

### BACKGROUND

A scanning-type distance measurement device that measures a distance to a measurement target by using a laser beam has been proposed. The distance measurement device includes a light projecting unit that performs two-dimensional scanning with, for example, a micro electro mechanical system (MEMS) mirror and performs irradiation using a laser beam (or a laser pulse) from a laser light source that emits light at a predetermined timing. The distance measurement device includes a light receiving unit that detects light reflected from the measurement target by a photodetector and calculates a distance to the measurement target for each scanning position with respect to the scanning of the laser beam using the light projecting unit.

For example, the distance measurement device may also be applied to a three-dimensional sensor device that detects a living body such as a human or an object such as a vehicle. For example, the three-dimensional sensor device may also detect an athlete such as a gymnast or a basketball player, and may measure a form of the athlete (for example, a performance form of the gymnast, a shooting form of the basketball player, or the like) or the like. The form or movement of the athlete may be analyzed based on the form measured by the three-dimensional sensor device.

For example, when the three-dimensional sensor device is used to measure the form of the gymnast or the like, a plurality of gymnasts may perform performances in the same, time, zone in a venue where the gymnasts, perform the performances. For example, when a plurality of different gymnastics (for example, floor, vault, or the like) is performed in the same time zone in the venue, a plurality of three-dimensional sensor devices is used to measure the forms of the plurality of gymnasts who performs different gymnastics or the like. In this case, since the plurality of three-dimensional sensor devices uses laser beams having different wavelengths, a filter that passes only a wavelength band of the laser beam used by each three-dimensional sensor device is provided in the light receiving unit of each three-dimensional sensor device. However, when the wavelength of the laser beam greatly deviates from a target value and deviates from a target wavelength band, the laser beam is cut by the filter of the light receiving unit that is originally to receive the laser beam, and the three-dimensional sensor device may not accurately measure the measurement target.

The wavelength of the laser beam emitted by a laser diode may be controlled by a voltage to be applied to the laser diode. However, the wavelength of the laser beam is changed depending on an environmental temperature in which the laser diode is used. The wavelength of the laser beam is also changed due to heat generated by the laser diode itself. The wavelength of the laser beam is also changed with time including a time when the laser diode is started. For example, when the laser diode is started, it takes a predetermined time until the wavelength of the laser beam becomes stable and is maintained at a predetermined wavelength. Thus, even though the voltage to be applied to the laser diode is controlled, the wavelength of the laser beam may not fall within the target wavelength band.

Examples of the related art are disclosed in Japanese Laid-open Patent Publication No. 2005-72890, Japanese Laid-open Patent Publication No. 2003-8138, and the like.

### SUMMARY

According to an aspect of the embodiments, a laser wavelength control device, includes a memory; and a processor coupled to the memory and configured to: measure a wavelength of a laser beam emitted by a light source, when the measured wavelength is not in a target wavelength band, adjust a voltage to be applied to the light source such that a wavelength of the laser beam falls within the target wavelength band, and when a wavelength measured after the adjustment of the voltage is not in the target wavelength band, adjust a temperature of the light source such that the wavelength of the laser beam falls within the target wavelength band.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating an example of a three-dimensional sensor device according to an embodiment;

FIG. 2 is a functional block diagram illustrating an example of an arithmetic circuit illustrated in FIG. 1;

FIG. 3 is a block diagram illustrating an example of a computer;

FIG. 4 is a flowchart for describing an example of distance measurement processing according to an embodiment;

FIG. 5 is a flowchart for describing an example of laser wavelength control processing according to an embodiment;

FIG. 6 is a diagram for describing an example of data stored in a memory;

FIG. 7 is a perspective view illustrating an example of an appearance of the laser wavelength control device;

FIG. 8 is an enlarged view of a portion of a laser diode;

FIG. 9 is an enlarged view of a portion of a Peltier element; and

FIG. 10 is a schematic diagram illustrating an example of a light source device together with a wavelength detector.

### DESCRIPTION OF EMBODIMENTS

In the related art, even though the voltage to be applied to the laser diode is controlled, it is difficult to control the wavelength of the laser beams to be maintained at the predetermined wavelength, and the wavelength of the laser beam may not be adjusted within the target wavelength band.

In view of such circumstances, it is desirable that the wavelength of the laser beam may be controlled to be maintained-at the predetermined wavelength.

In the disclosed laser wavelength control device and method for controlling a laser wavelength, a voltage to be applied to a light source is adjusted such that a wavelength of a laser beam falls within a target wavelength band while referring to data on the voltage to be applied to the light source, a temperature of the light source, and the wavelength of the laser beam to be emitted by the light source which are obtained in advance when a measured value of the wavelength of the laser beam emitted by the light source is not in the target wavelength band. The temperature of the light source is adjusted such that a wavelength of the laser beam at the adjusted voltage falls within the target wavelength band while referring to the data when the wavelength measured at the adjusted voltage is not in the target wavelength band.

Hereinafter, embodiments of a laser wavelength control device and a method for controlling a laser wavelength according to the present disclosure will be described with reference to the drawings.

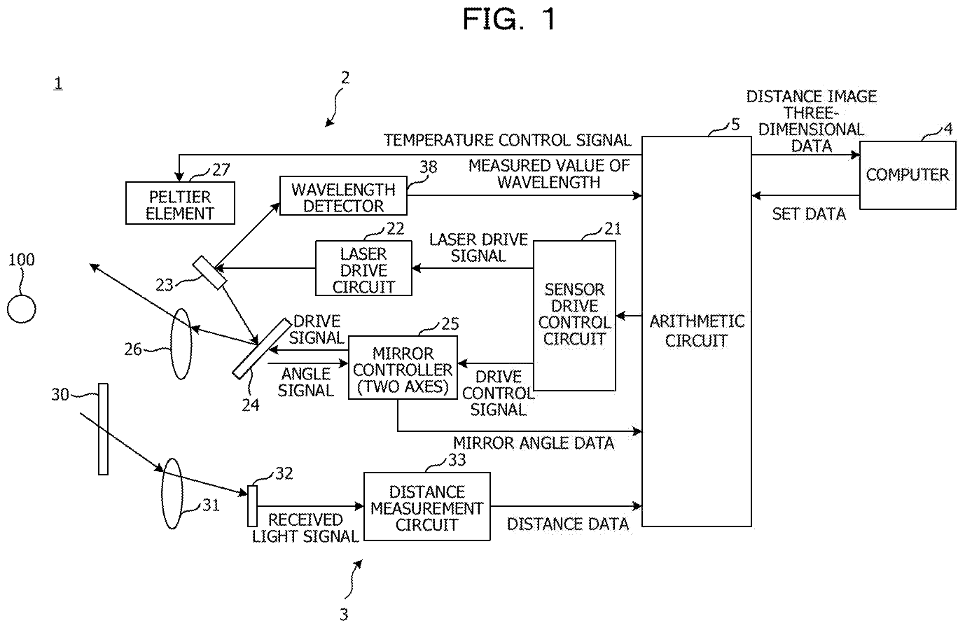

FIG. 1 is a diagram illustrating an example of a three-dimensional sensor device according to an embodiment. The three-dimensional sensor device illustrated in FIG. 1 includes a sensor main body 1 and a computer 4. The sensor main body 1 includes a light projecting unit 2, a light receiving unit 3, and an arithmetic circuit 5. As will be described later, the laser wavelength control device according to the present embodiment may be formed of, for example, the computer 4.

The light projecting unit 2 includes a sensor drive control circuit 21, a laser drive circuit 22, a laser diode 23 as an example of a light source, a two-axis scanning mirror 24, a two-axis mirror controller 25, a light projecting lens 26, and a Peltier element 27. The sensor drive control circuit 21 supplies a laser drive signal indicating a light emission timing of the laser diode 23 and a wavelength of a laser beam to be emitted to the laser drive circuit 22. The laser drive circuit 22 causes the laser diode 23 to emit light at the light emission timing indicated by the laser drive signal, and causes the laser diode 23 to emit the laser beam having the wavelength indicated by the laser drive signal. The sensor drive control circuit 21 supplies a drive control signal for driving the scanning mirror 24 on two axes to the mirror controller 25.

The mirror controller 25 outputs the drive signal for driving the scanning mirror 24 on two axes in accordance with the drive control signal, and drives the scanning mirror 24 by a well-known drive unit (not illustrated). The scanning mirror 24 is formed of, for example, a two-dimensional micro electro mechanical system (MEMS) mirror. A mirror angle of the scanning mirror 24 is detected by a well-known detection unit (not illustrated), and an angle signal indicating the mirror angle is supplied to the mirror controller 25. In FIG. 1, the scanning mirror 24 is illustrated as including the above-described drive unit and detection unit for the sake of convenience in description. The mirror controller 25 generates mirror angle data indicating the mirror angle of the scanning mirror 24 in accordance with the angle signal, and supplies the mirror angle data to the arithmetic circuit 5. Accordingly, the laser beam emitted by the laser diode 23 is deflected by the scanning mirror 24, and scans a scanning angle range via the light projecting lens 26, for example, performs raster scanning.

By such raster scanning, the laser beam (or a laser pulse) scans a measurement range at a position separated from the sensor main body 1 by a certain distance. For example, the measurement range has a width corresponding to a distance by which the laser beam moves from one end to the other end of the scanning angle range substantially in parallel with a horizontal plane (or the ground) at a position separated from the sensor main body 1 by a certain distance. For example, the measurement range has a height corresponding to a distance by which the laser beam moves in a direction perpendicular to the horizontal plane from the lowest point to the highest point. For example, the measurement range refers to the entire region scanned by the laser beam at a position separated from the sensor main body 1 by a predetermined distance.

The Peltier element 27 is provided at a position near the laser diode 23 where the laser diode 23 may be heated and cooled. The Peltier element 27 is an example of means for heating or cooling the laser diode 23 in accordance with a temperature control signal from the arithmetic circuit 5. The Peltier element 27 has a known configuration in which a temperature changes in accordance with the temperature control signal. The control of the Peltier element 27 will be described later.

A wavelength detector 38 is an example of measurement means for measuring the wavelength of the laser beam based on a light component extracted in a direction different from a direction in which the laser diode 23 emits the laser beam toward the scanning mirror 24. The wavelength detector 38 is configured to detect the wavelength of the light component to be input and output a measured value of the wavelength to the arithmetic circuit 5. In this example, the wavelength detector 38 is separate from the light projecting unit 2 (for example, the sensor main body 1), but may form a part of the light projecting unit 2 (for example, the sensor main body 1). The control of the laser diode 23 based on the measured value of the wavelength output by the wavelength detector 38 will be described later.

The light receiving unit 3 includes a filter 30, a light receiving lens 31, a photodiode 32 as an example of a photodetector, and a distance measurement circuit 33. Light reflected from a measurement target 100 is, detected by the photodiode 32 via the filter 30 and the light receiving lens 31. The filter 30 has a well-known configuration that allows only a laser beam in a target wavelength band used by the three-dimensional sensor device to pass therethrough. The photodiode 32 supplies a received light signal indicating the detected reflected light to the distance measurement circuit 33. The distance measurement circuit 33 measures a turnaround time (time of flight: TOF) ΔT from when the laser beam is emitted from the light projecting unit 2 to when the laser beam is reflected from the measurement target 100 and returns to the light receiving unit 3. The distance measurement circuit 33 optically measures a distance to the measurement target 100 in this manner, and supplies distance data indicating the measured distance to the arithmetic circuit 5. When a speed of light is represented by c (about 300,000 km/s), the distance to the measurement target 100 may be obtained from, for example, (c×ΔT)/2.

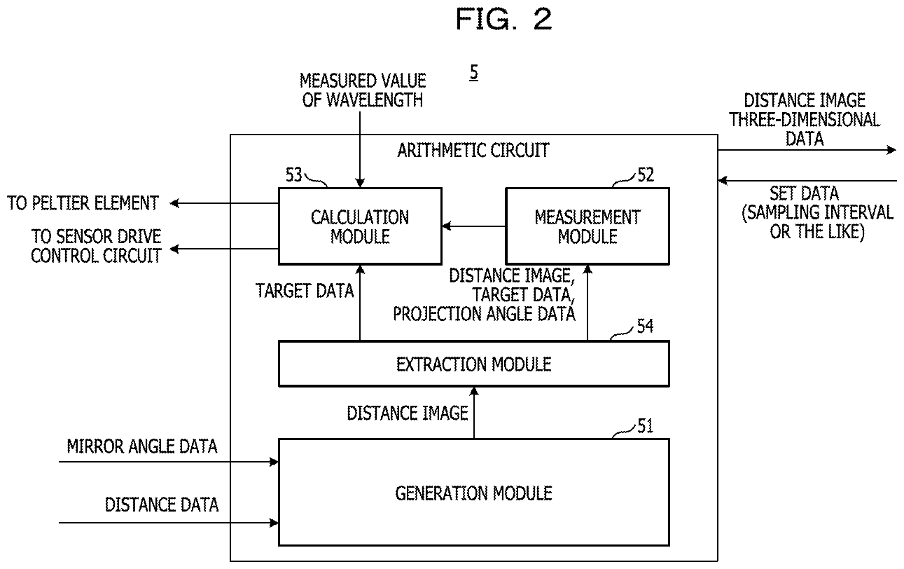

FIG. 2 is a functional block diagram illustrating an example of the arithmetic circuit illustrated in FIG. 1. The arithmetic circuit 5 may be formed of, for example, a processor. The processor executes a function of each of modules 51 to 54 illustrated in FIG. 2 by executing a program stored in a memory. In this example, the arithmetic circuit 5 includes a generation module 51, a measurement module 52, a calculation module 53, and an extraction module 54. The arithmetic circuit 5 changes the measurement range such that a sampling interval (or density) is equal to or greater than a predetermined value according to the measured distance to the measurement target and a detected azimuth of the measurement target. The changing of the measurement range means increasing or decreasing a size of the measurement range. The size of the measurement range is increased by increasing a width of the scanning angle range, and is decreased by decreasing the width of the scanning angle range.

The generation module 51 inputs the mirror angle data and the distance data, generates a distance image from the distance data, and generates three-dimensional data from, the distance image and the mirror angle data. The generation module 51 generates projection angle data indicating a projection angle of the laser beam from the mirror angle data. The distance image is an image in which distance values at the respective distance measurement points are arranged in the order of raster-scanned samples. The three-dimensional data may be generated by conversion using the distance values and the projection angle data. The three-dimensional data may be output to the computer 4. Similarly, the distance image may also be output to the computer 4.

When the measurement target 100 is present within the raster-scanned scanning angle range, the extraction module 54 extracts the measurement target 100 from the distance image. A method for extracting the measurement target 100 from the distance image is not particularly limited. For example, the measurement target 100 may be extracted by a known method. For example, when the measurement target 100 is a human, the measurement target 100 may be extracted by detecting a shape such as a posture that the human may take from the distance image. As another example in which the target is designated, an extraction method for displaying the acquired distance image or a three-dimensional image on a display and designating (clicking) a desired position on a screen of the display with a mouse or the like or designating a range may be adopted. The extraction module 54 supplies the projection angle data, the distance data, and data on the extracted measurement target 100 (hereinafter, also referred to as “target data”) to the measurement module 52, and supplies the target data to the calculation module 53.

The measurement module 52 calculates a distance to a position of a center of gravity of the measurement target 100 from the extracted target data, and calculates an azimuth angle to, for example, the position of the center of gravity of the measurement target 100 from the projection angle data and the extracted target data. A method for calculating the center of gravity of the measurement target 100 is not particularly limited, and the center of gravity may be calculated by a known method, for example. A method for calculating the azimuth angle to the measurement target 100 is not particularly limited, and the azimuth angle may be calculated by a known method, for example.

The calculation module 53 calculates the respective set values of the scanning angle range and a shift amount of the scanning angle range based on the distance to the position of the center of gravity of the measurement target 100 and the azimuth angle. For example, the calculation module 53 calculates the respective set values of the scanning angle range and the shift amount of the scanning angle range such that a desired sampling interval input from the computer 4 in advance is achieved and the measurement target 100 is detected near a center of the scanning angle range. The calculation module 53 supplies the set values to the sensor drive control circuit 21, and proceeds to the next measurement. The center of the scanning angle range may be shifted by shifting the scanning angle range, and thus, a region covered by the scanning angle range may be changed.

The calculation module 53 may refer to data on the voltage to be applied to the laser diode 23, the temperature of the laser diode 23, and the wavelength of the laser beam to be emitted by the laser diode 23 which are obtained in advance. This data is stored in advance in the three-dimensional sensor device or in an external storage device (not illustrated) accessible by the calculation module 53. When the measured value of the wavelength from the wavelength detector 38 is not within the target wavelength band, the calculation module 53 adjusts the voltage to be applied to the laser diode 23 such that the measured value of the wavelength falls within the target wavelength band while referring to the data. When the measured value of the wavelength is not within the target wavelength band after the voltage adjustment, the calculation module 53 adjusts the temperature of the laser diode 23 such that the measured value of the wavelength fails within the target wavelength band by controlling the heating or cooling of the laser diode 23 by the Peltier element 27 while referring to the data.

The calculation module 53 is an example of setting means for setting a mirror drive condition and a laser drive condition for the sensor drive control circuit 21 and setting a drive condition of the Peltier element 27. The mirror drive condition is a condition for supplying the drive control signal for driving the scanning mirror 24 on two axes to the mirror controller 25. The laser drive condition is a condition for supplying the laser drive signal indicating the light emission timing of the laser diode 23 and the wavelength of the laser beam to be emitted to the laser drive circuit 22. The drive condition of the Peltier element 27 is a condition for supplying the temperature control signal for heating or cooling the laser diode 23 to the Peltier element 27. Thus, when the measured value of the wavelength from the wavelength detector 38 is not within the target wavelength band, the calculation module 53 controls the laser drive signal while referring to the data. The voltage to be applied to the laser diode 23 is adjusted such that the measured value of the wavelength falls within the target wavelength band by controlling the laser drive signal. When the measured value of the wavelength at the adjusted voltage is not within the target wavelength band, the calculation module 53 controls the temperature control signal while referring to the data. The temperature of the laser diode 23 is adjusted by heating or cooling the Peltier element 27 such that the measured value of the wavelength at the adjusted voltage falls within the target wavelength band by controlling the temperature control signal.

An environmental temperature at which the laser diode 23 is used is generally not maintained at a predetermined temperature but is changed. The temperature of the laser diode 23 is also changed due to heat generated by the laser diode 23 itself. It takes a predetermined time from when the temperature of the laser diode 23 is changed at the start of the laser diode 23 to when the temperature is stabilized. Thus, in the present embodiment, in order for the wavelength of the laser beam to fall within the target wavelength band by controlling the wavelength to be maintained at a predetermined wavelength, the voltage to be applied to the laser diode 23 is first adjusted, and then the temperature of the laser diode 23 is adjusted in case of necessity.

The arithmetic circuit 5 may perform the measurement in which an interval between sampling points (or distance measurement points) using the laser beam (for example, sampling interval) is equal to or greater than the predetermined value even though the distance to the measurement target 100 is changed by repeating the above-described processing. The arithmetic circuit 5 controls the voltage and temperature of the laser diode 23 such that the wavelength of the laser beam emitted by the laser diode 23 falls within the target wavelength band by repeating the above-described processing under the control of the computer 4.

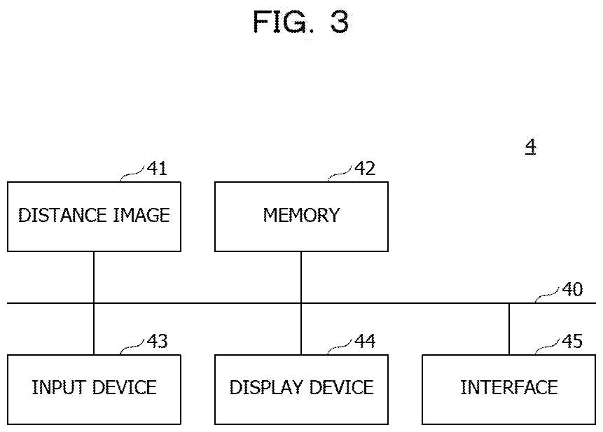

The computer 4 may have, for example, a configuration illustrated in FIG. 3. FIG. 3 is a block diagram illustrating an example of the computer. The computer 4 illustrated in FIG. 3 includes a processor 41, a memory 42, an input device 43, a display device 44, and an interface (or a communication device) 45 which are coupled to each other via a bus 40. For example, the processor 41 may be formed of a central processing unit (CPU) or the like, and controls the entire computer 4 by executing a program stored in the memory 42. The memory 42 may be formed of, for example, a computer-readable storage medium such as a semiconductor storage device, a magnetic recording medium, an optical recording medium, or a magneto-optical recording medium. The memory 42 stores various programs including a laser wavelength control program, a distance measurement program, and the like executed by the processor 41, various kinds of data, and the like. The various kinds of data stored in the memory 42 include data on the voltage to be applied to the laser diode 23, the temperature of the laser diode 23, and the wavelength of the laser beam to be emitted by the laser diode 23 which are obtained in advance. A format of the data on the voltage, temperature, and wavelength stored in the memory 42 is not particularly limited. In this example, the memory 42 is an example of a storage device in the three-dimensional sensor device.

For example, the input device 43 may be formed of a keyboard or the like operated by a user (or an operator), and is used to input commands and data to the processor 41. The display device 44 displays a message for the user, a measurement result of distance measurement processing, and the like. The interface 45 couples the computer 4 to another computer or the like so as to be able to communicate. In this example, the computer 4 is coupled to the arithmetic circuit 5 via the interface 45.

The computer 4 is not limited to a hardware configuration in which the components of the computer 4 are coupled via the bus 40. For example, a general-purpose computer may be used as the computer 4.

The input device 43 and the display device 44 of the computer 4 may be omitted. In the case of a module, a semiconductor chip, or the like in which the interface 45 of the computer 4 is further omitted, an output of the sensor main body 1 (for example, an output of the arithmetic circuit 5) may be coupled to the bus 40 or directly coupled to the processor 41. For example, when the computer 4 is formed of a semiconductor chip or the like, the semiconductor chip or the like may be provided in the sensor main body 1. The computer 4 may include, for example, the arithmetic circuit 5.

When the measured value of the wavelength from the wavelength detector 38 is not within the target wavelength band, the computer 4 adjusts the voltage to be applied to the laser diode 23 such that the wavelength of the laser beam falls within the target wavelength band while referring to the data stored in the memory 42. When the measured value at the adjusted voltage is not within the target wavelength band, the computer 4 adjusts the temperature of the laser diode 23 such that the wavelength of the laser beam at the adjusted voltage falls within the target wavelength band by controlling the Peltier element 27 while referring to the data stored in the memory 42. Accordingly, the computer 4 forms an example of adjustment means for adjusting the voltage and temperature of the laser diode 23 such that the measured value of the wavelength falls within the target wavelength band.

For example, the laser wavelength control device according to the present embodiment may include the computer 4, and the computer 4 may include at least a part of the arithmetic circuit 5. The laser wavelength control device may include the wavelength detector 38.

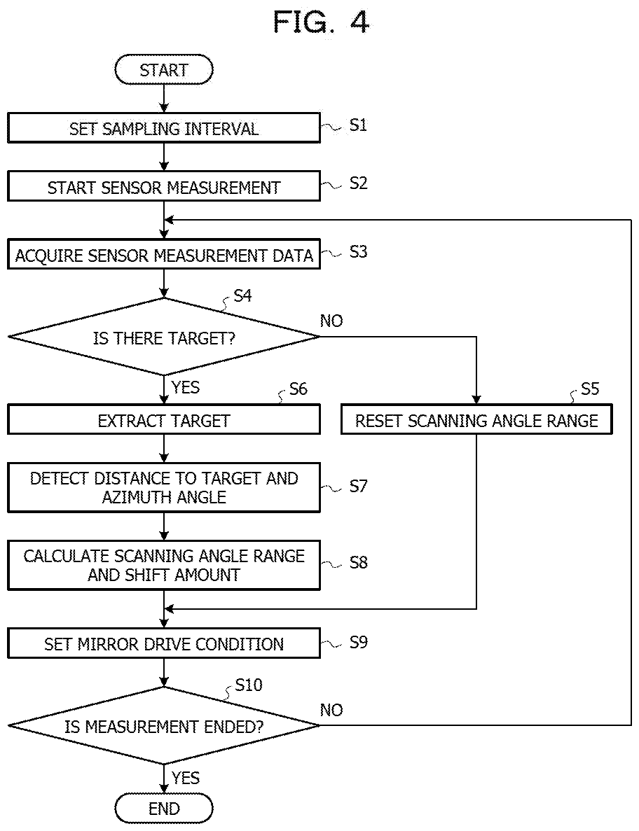

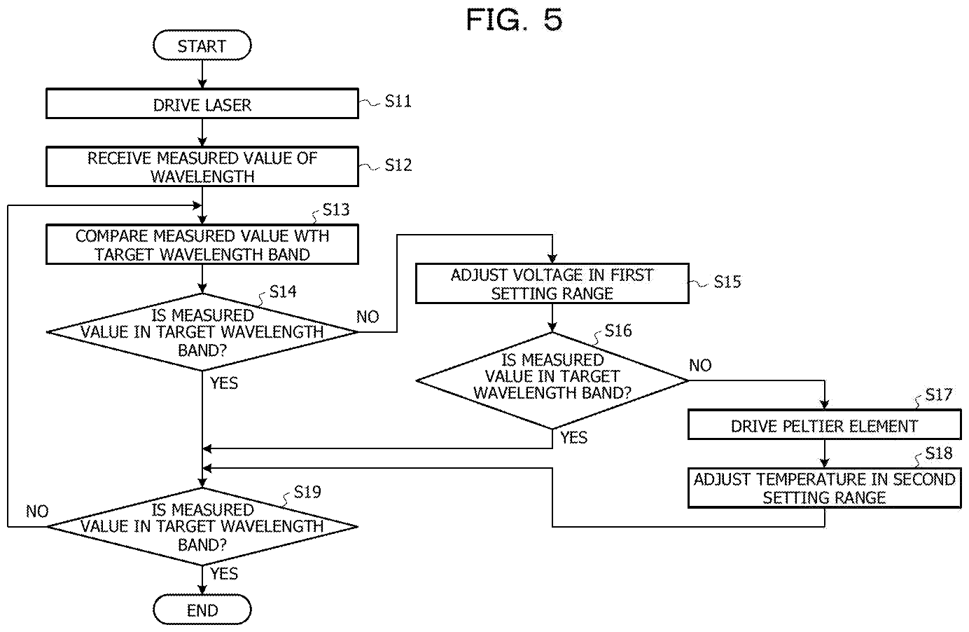

FIG. 4 is a flowchart for describing an example of distance measurement processing according to an embodiment. In FIG. 4, in step S1, the computer 4 starts the distance measurement processing, and sets set data including the sampling interval. When the distance measurement processing is started, the processor 41 of the computer 4 starts laser wavelength control processing to be described later with reference to FIG. 5 by executing the laser wavelength control program stored in the memory 42. In step S2, the computer 4 starts measurement using the sensor main body 1.

In step S3, the generation module 51 of the arithmetic circuit 5 acquires measurement data from the sensor main body 1. The acquired measurement data includes the distance data from the distance measurement circuit 33 and the mirror angle data from the mirror controller 35. Accordingly, in step S3, the generation module 51 generates the three-dimensional data from the distance data, generates the distance image from the three-dimensional data, and generates the projection angle data from the mirror angle data. The three-dimensional data may be output to the computer 4 in case of necessity.

In step S4, the extraction module 54 of the arithmetic circuit 5 determines whether or not the measurement target 100 is present within the raster-scanned scanning angle range. When the determination result is NO, the processing proceeds to step S5, and when the determination result is YES, the processing proceeds to step S6. Whether or not the measurement target 100 is present within the raster-scanned scanning angle range may be determined by a known method.

In step S5, since the target data is not output from the extraction module 54, the calculation module 53 of the arithmetic circuit 5 resets the scanning angle range to a maximum scanning angle range, and the processing proceeds to step S9 to be described later. In step S6, when the measurement target 100 is present within the raster-scanned scanning angle range, the extraction module 54 of the arithmetic circuit 5 extracts the measurement target 100 from the distance image, and obtains the target data of the extracted measurement target 100.

In step S7, the measurement module 52 of the arithmetic circuit 5 calculates the distance to the position of the center of gravity of the measurement target 100 and the azimuth angle from the extracted target data and projection angle data, and stores the distance and the azimuth angle in case of necessity.

In step S8, the calculation module 53 of the arithmetic circuit 5 calculates the respective set values of the scanning angle range and the shift amount of the scanning angle range so as to achieve the desired sampling interval input from the computer 4 in advance based on the distance to the position of the center of gravity of the measurement target 100 and the azimuth angle calculated or stored in step S7. In step S9, the calculation module 53 of the arithmetic circuit 5 sets, for the sensor drive control circuit 21, the mirror drive condition for supplying the drive control signal for driving the scanning mirror 24 on two axes to the mirror controller 25. For example, the calculation module 53 supplies the respective set values of the calculated scanning angle range and the shift amount of the scanning angle range to the sensor drive control circuit 21. When the scanning angle range is reset in step S5, the mirror drive condition is set based on the reset scanning angle range in step S9.

In step S10, the computer 4 determines whether or not the distance measurement processing is ended. When the determination result is NO, the processing returns to step S3, and when the determination result is YES, the processing is ended. Accordingly, measurement in which the sampling interval is equal to or greater than the predetermined value may be performed even though the distance to the measurement target 100 is changed by repeating the above-described processing until the determination result in step S10 becomes YES.

According to the present embodiment, the distance to the measurement target may be measured at the sampling interval equal to or greater than the predetermined value within the measurement range even though the distance to the measurement target is changed. Accordingly, both a demand for stably performing high-accuracy measurement by increasing the measurement range and a demand for performing high-resolution measurement by decreasing the sampling interval within the measurement range may be satisfied.

FIG. 5 is a flowchart for describing an example of the laser wavelength control processing according to an embodiment. The laser wavelength control processing illustrated in FIG. 5 is executed by the processor 41 of the computer 4 executing the laser wavelength control program stored in the memory 42.

In FIG. 5, in step S11, the processor 41 drives the laser diode 23 by supplying the laser drive signal to the laser drive circuit 22 via the arithmetic circuit 5 and the sensor drive control circuit 21. Thus, the laser drive circuit 22 applies a voltage of an initial value to the laser diode 23, and the laser diode 23 emits the laser beam having the light emission timing and the wavelength indicated by the laser drive signal.

In step S12, the processor 41 starts receiving the measured value of the wavelength of the laser beam detected by the wavelength detector 38 via the arithmetic circuit 5. In step S13, the processor 41 compares the measured value of the wavelength of the laser beam with the target wavelength band. In step S14, the processor 41 determines whether or not the measured value of the wavelength of the laser beam is within the target wavelength band. When the determination result is NO, the processing proceeds to step S15, and when the determination result is YES, the processing proceeds to step S19.

In step S15, the processor 41 acquires a first setting range of the voltage for adjusting the wavelength of the laser beam within the target wavelength band while referring to the data stored in the memory 42, and adjusts the voltage to be applied to the laser diode 23 within the first setting range. The voltage to be applied to the laser diode 23 may be adjusted within the first setting range such that the wavelength of the laser beam becomes a center wavelength of the target wavelength band. An upper limit of the first setting range of the voltage is determined in advance in accordance with, for example, a maximum allowable output of the laser diode 23.

In step S16, the processor 41 determines whether or not the measured value of the wavelength of the laser beam received from the wavelength detector 38 at the adjusted voltage is within the target wavelength band. When the determination result is NO, the processing proceeds to step S17, and when the determination result is YES, the processing proceeds to step S19.

In step S17, the processor 41 starts driving the Peltier element 27 via the arithmetic circuit 5. In step S18, the processor 41 acquires a second setting range of the temperature of the laser diode 23 for adjusting the wavelength of the laser beam within the target wavelength band while referring to the data stored in the memory 42. In step S18, the processor 41 supplies the temperature control signal to the Peltier element 27 via the arithmetic circuit 5 so as to adjust the temperature of the laser diode 23 within the second setting range. The temperature of the laser diode 23 may be adjusted within the second setting range such that the wavelength of the laser beam becomes the center wavelength of the target wavelength band. An upper limit of the second setting range of the temperature is determined in advance to a temperature that does not reach in a normal operation, for example, in accordance with a heat-resistant temperature of the laser diode 23. After step S18, the processing proceeds to step S19.

In step S19, the processor 41 determines whether or not the measured value of the wavelength of the laser beam received from the wavelength detector 38 after the temperature adjustment is within the target wavelength band. When the determination result is NO, the processing returns to step S13, and when the determination result is YES, the processing is ended.

Accordingly, the wavelength of the laser beam may be controlled to be maintained at the predetermined wavelength even though the temperature of the laser diode is changed by adjusting the voltage and then adjusting the temperature in case of necessity such that the measured value of the wavelength of the laser beam falls within the target wavelength band.

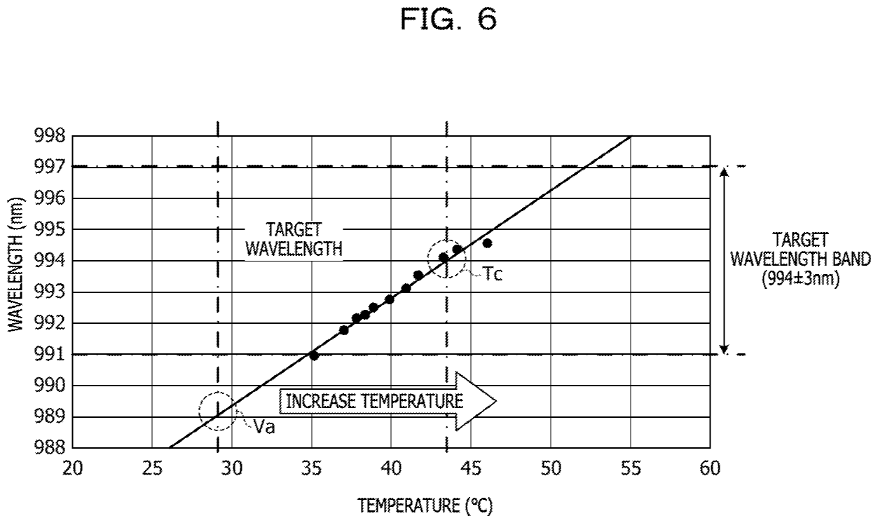

FIG. 6 is a diagram for describing an example of the data stored in the memory. In FIG. 6, a vertical axis represents a wavelength (nm) of the laser beam, and a horizontal axis represents a temperature (° C.) of the laser diode 23. The data stored in the memory 42 includes the data on the voltage to be applied to the laser diode 23, the temperature of the laser diode 23, and the wavelength of the laser beam to be emitted by the laser diode 23. The data also includes the first setting range of the voltage for adjusting the wavelength of the laser beam within the target wavelength band and the second setting range of the temperature of the laser diode 23 for adjusting the wavelength of the laser beam within the target wavelength band.

In FIG. 6, the wavelength of the laser beam for an example of an adjusted voltage Va is indicated by being surrounded by a broken line O. In this example, the target wavelength band of the laser beam is 994±3 nm, and the target wavelength which is the center wavelength of the target wavelength band is 994 nm. The wavelength of the laser beam at the adjusted voltage Va is about 989 nm outside the target wavelength band, and the temperature of the laser diode 23 is about 29° C. Since a certain amount of time elapses after the laser diode 23 is driven and the temperature of the laser diode 23 after the voltage adjustment and before the temperature adjustment is more stabilized than the temperature at the start of the laser diode, the temperature of the laser diode may be obtained in advance and stored in the memory 42 together with the data on the voltage. Accordingly, the configuration of the three-dimensional sensor device and the laser wavelength control processing are restrained from being complicated as compared with a case where a temperature sensor is provided in the three-dimensional sensor device and the temperature of the laser diode 23 is continuously monitored. Since the wavelength of the laser beam after the adjustment of the voltage and the temperature may fall within the target wavelength band, the temperature of the laser diode 23 after the voltage adjustment and before the temperature adjustment which is obtained in advance may not be obtained with high accuracy, and for example, an average value or a value with a margin may be used.

The temperature of the laser diode 23 is adjusted as indicated by an arrow, for example, to be equal to the temperature of the Peltier element 27 such that the measured value of the wavelength of the laser beam received from the wavelength detector 38 at the adjusted voltage falls within the target wavelength band. In this example, the Peltier element 27 is controlled such that the temperature of the laser diode 23 rises. As illustrated by the data of FIG. 6, it is understood that the wavelength of the laser beam may be controlled to the target wavelength of the target wavelength band by the Peltier element 27 heating the laser diode 23 to raise the temperature to a temperature Tc (about 43° C.) indicated by the broken line O.

It is desirable that the data on the voltage to be applied to the laser diode 23, the temperature of the laser diode 23, and the wavelength of the laser beam to be emitted by the laser diode 23 including the data illustrated in FIG. 6 is obtained in advance for each laser diode 23 and stored in the memory 42. In this case, the wavelength of the laser beam may be controlled to be maintained at the predetermined wavelength in accordance with characteristics of each individual laser diode 23 and the environmental temperature.

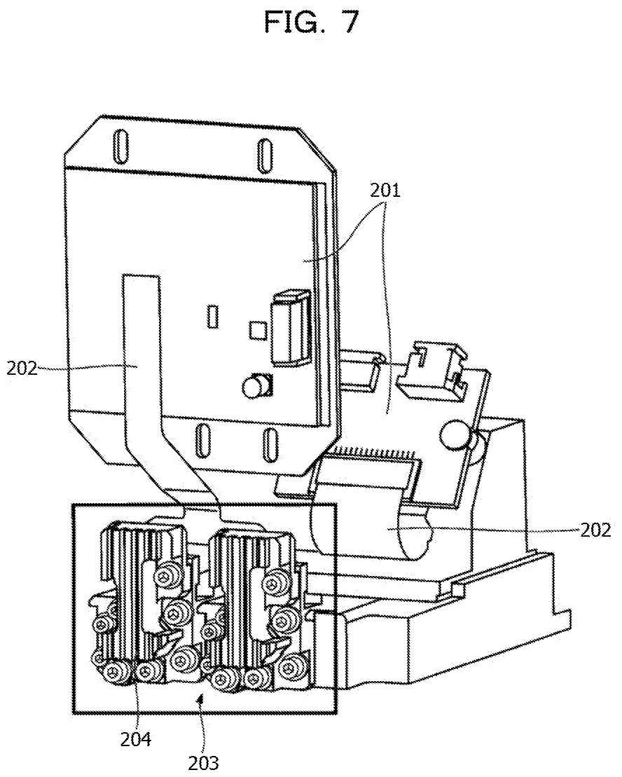

FIG. 7 is a perspective view illustrating an example of an appearance of the laser wavelength control device. The laser wavelength control device illustrated in FIG. 7 includes circuit boards 201, flexible printed circuits (FPCs) 202, a light source device 203, a heat sink 204, and the like. The arithmetic circuit 5, the sensor drive control circuit 21, the laser drive circuit 22, the distance measurement circuit 33, and the like illustrated in FIG. I are provided at the circuit board 201. Each of the FPCs 202 electrically couples the, circuit board 201 and the light source device 203, the circuit boards 201, or the like. The heat sink 204 is provided in the light source device 203. Although the laser diode 23 and the like of the light source device 203 are not seen in FIG. 7, the laser beam emitted from the laser diode 23 is projected in a direction perpendicular to a surface of the heat sink 204 seen from the front in FIG. 7 and toward the inside of the laser wavelength control device.

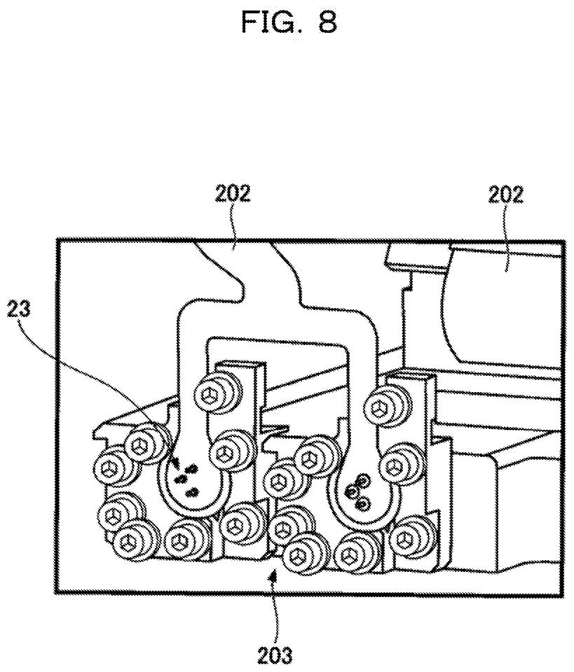

FIG. 8 is an enlarged view of a portion of the laser diode. FIG. 8 illustrates a state in which the heat sink 204 and the Peltier element 27 are removed. In this example, the laser diode 23 of the light source device 203 is provided in a housing of the laser wavelength control device, and the FPC 202 provided over the laser diode 23 is electrically coupled to the laser diode 23. In this example, the laser diode 23 is provided in plural.

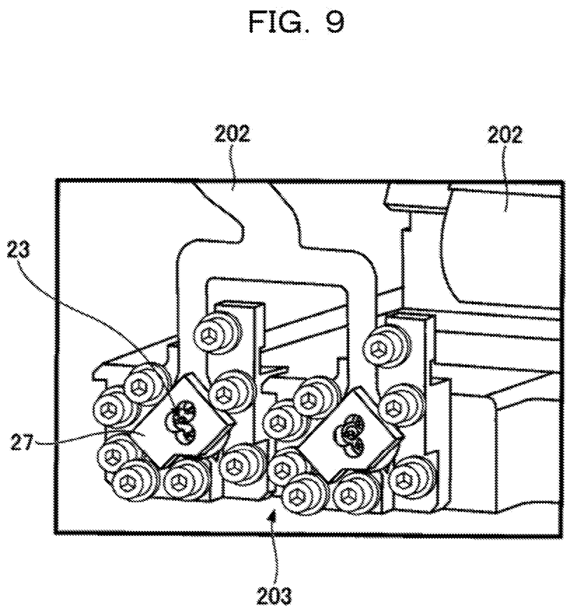

FIG. 9 is an enlarged view of a portion of the Peltier element. FIG. 9 illustrates a state in which the heat sink 204 is removed. In this example, the Peltier element 27 is provided over the laser diodes 23 via the FPC 202, and a part of each laser diode 23 is disposed in the corresponding opening of the Peltier element 27. In the state illustrated in FIG. 9, the heat sink 204 illustrated in FIG. 7 is provided over the Peltier element 27.

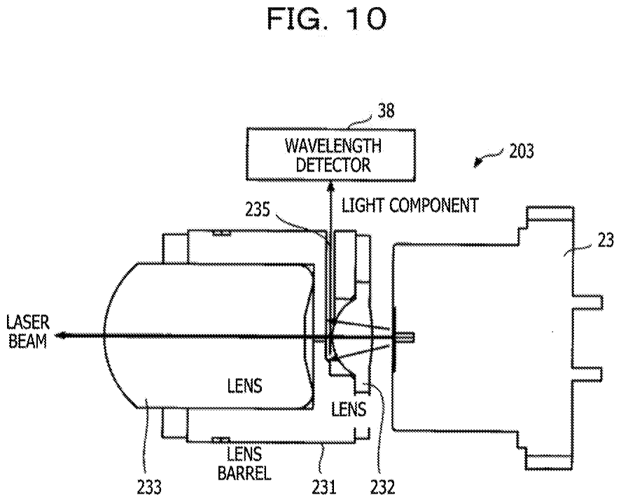

FIG. 10 is a schematic diagram illustrating an example of a light source device together with a wavelength detector. As illustrated in FIG. 10, the light source device 203 includes the laser diode 23, a lens barrel 231, a lens system which is provided in a lens barrel 231 and includes lenses 232 and 233, and a branch portion 235. The lens system guides the laser beam from the laser diode 23 in a first direction. The branch portion 235 includes a light path which is provided in the lens barrel 231 and extracts a light component of the laser beam passing through a part of the lens system to the outside of the lens barrel 23 in a second direction different from the first direction. For example, the first direction and the second direction are orthogonal to each other. In this example, the lens barrel 231 is made of a material through which the laser beam is not transmitted, and the light path of the branch portion 235 is formed by an opening provided in the lens barrel 231. Thus, the light component for measuring the wavelength of the laser beam may be extracted to the side of the light source device 203 (upward in FIG. 10) with a relatively simple configuration without significantly reducing the intensity of the laser beam emitted from the light source device 203. The light component extracted to the outside of the lens barrel 231 is input to the wavelength detector 38, and the wavelength detector 38 detects the wavelength of the light component.

According to the above-described embodiments, the wavelength of the laser beam may be controlled to be maintained at the predetermined wavelength. Thus, the wavelength of the laser beam emitted from the light source may be adjusted such as the laser diode to fall within the target wavelength band.

With respect to the embodiment including the above-described embodiments, the following appendices are further disclosed.

(Appendix 1)

There is provided a laser wavelength control device including adjustment means for adjusting a voltage to be applied to a light source such that a wavelength of a laser beam falls within a target wavelength band while referring to data on the voltage to be applied to the light source, a temperature of the light source, and a wavelength of the laser beam to be emitted by the light source which are obtained in advance when a measured value of the wavelength of the laser beam emitted by the light source is not in the target wavelength band, and adjusting the temperature of the light source such that the measured value of the wavelength of the laser beam at the adjusted voltage falls within the target wavelength band while referring to the data when a measured value of the wavelength at the adjusted voltage is not in the target wavelength band.

(Appendix 2)

There is provided a laser wavelength control device including measurement means for measuring a wavelength of a laser beam based on a light component extracted in a direction different from a direction in which a light source emits the laser beam, and

adjustment means for adjusting a voltage to be applied to the light source such that the wavelength of the laser beam falls within a target wavelength band while referring to data on the voltage to be applied to the light source, a temperature of the light source, and the wavelength of the laser beam to be emitted by the light source which are obtained in advance when the measured wavelength of the laser beam is not in the target wavelength band, and adjusting the temperature of the light source such that the wavelength of the laser beam at the adjusted voltage falls within the target wavelength band while referring to the data when the wavelength measured at the adjusted voltage is not in the target wavelength band.

(Appendix 3)

In the laser wavelength control device according to appendix 1 or 2, the adjustment means adjusts the voltage in a first setting range included in the data such that the wavelength of the laser beam becomes a center wavelength of the target wavelength band.

(Appendix 4)

In the laser wavelength control device according to appendix 3, an upper limit of the first setting range is determined in advance in accordance with a maximum allowable output of the light source.

(Appendix 5)

The laser wavelength control device according to any one of appendices 1 to 4 further includes means for heating or cooling the light source so as to adjust the temperature in a second setting range included in the data such that the wavelength of the laser beam becomes a center wavelength of the target wavelength band.

(Appendix 6)

In the laser wavelength control device according to appendix 5, the means for heating or cooling the light source is a Peltier element controlled such that the temperature falls in the second setting range by the adjustment means.

(Appendix 7)

In the laser wavelength control device according to appendix 5 or 6, an upper limit of the second setting range is determined in advance in accordance with a heat-resistant temperature of the light source.

(Appendix 8)

The laser wavelength control device according to any one of appendices 1 to 7 further includes a light source device that includes the light source and a branch portion, wherein

the light source includes a laser diode that emits the laser beam in a first direction, and

the branch portion extracts a light component of the laser be emitted from the laser diode in a second direction different from the first direction.

(Appendix 9)

In the laser wavelength control device according to appendix 8, the light source device further includes a lens barrel, and a lens system that is provided in the lens barrel and guides the laser beam from the laser diode in the first direction, and

the branch portion includes a light path that is provided in the lens barrel and extracts the light component of the laser beam passing through a part of the lens system toward an outside of the lens barrel in the second direction.

(Appendix 10)

There is provided a three-dimensional sensor device that two-dimensionally scans a scanning angle range with a laser beam and detects a measurement target in a measurement range.

The three-dimensional sensor device includes the laser wavelength control device according to any one of appendices 1 to 9,

a light projecting unit that includes the light source and a scanning mirror, and

a light receiving unit that includes a filter which passes a predetermined wavelength range and a photodetector.

(Appendix 11)

There is provided a laser wavelength control method including

measuring a wavelength of a laser beam emitted by a light source,

adjusting a voltage to be applied to the light source such that the wavelength of the laser beam falls within a target wavelength band while referring to data on the voltage to be applied to the light source, a temperature of the light source, and the wavelength of the laser beam to be emitted by the light source which are obtained in advance when the measured wavelength is not in the target wavelength band, and

adjusting the temperature of the light source such that a wavelength of the laser beam at the adjusted voltage falls within the target wavelength band while referring to the data when the wavelength measured at the adjusted voltage is not in the target wavelength band.

(Appendix 12)

In the method for controlling a laser wavelength according to appendix 11, in the adjusting of the voltage, the voltage is adjusted in a first setting range included in the data such that the wavelength of the laser beam becomes a center wavelength of the target wavelength band.

(Appendix 13)

In the method for controlling a laser wavelength according to appendix 12, an upper limit of the first setting range is determined in advance in accordance with a maximum allowable output of the light source.

(Appendix 14)

In the method for controlling a laser wavelength according to any one of appendices 11 to 13, in the adjusting of the temperature, the light source is heated or cooled so as to adjust the temperature in a second setting range included in the data such that the wavelength of the laser beam becomes a center wavelength of the target wavelength band.

(Appendix 15)

In the method for controlling a laser wavelength according to appendix 14, in the adjusting of the temperature, a Peltier element is controlled such that the temperature falls in the second setting range.

(Appendix 16)

In the method for controlling a laser wavelength according to appendix 14 or 15, an upper limit of the second setting range is determined in advance in accordance with a heat-resistant temperature of the light source.

(Appendix 17)

In the method for controlling a laser wavelength according to any one of appendices 11 and 16, in the measuring of the wavelength, the wavelength of the laser beam is measured based on a light component extracted in a direction different from a direction in which the light source emits the laser beam.

Although the disclosed laser wavelength control device and method for controlling a laser wavelength have been described with reference to the embodiments, the present disclosure is not limited to the above-described embodiments, and it goes without saying that various modifications and improvements may be made within the scope of the present disclosure.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A laser wavelength control device, comprising:
a memory; and
a processor coupled to the memory and configured to:
measure a wavelength of a laser beam emitted by a light source,
when the measured wavelength is not in a target wavelength band, adjust a voltage to be applied to the light source such that the wavelength of the laser beam falls within the target wavelength band, and
when a wavelength measured after the adjustment of the voltage is not in the target wavelength band, adjust a temperature of the light source such that the wavelength of the laser beam falls within the target wavelength band.

2. The laser wavelength control device according to claim 1, wherein the processor is configured to:
receive data which includes the voltage to be applied to the light source, the temperature of the light source, and the wavelength of the laser beam to be emitted by the light source, and
adjust the voltage in a first setting range included in the data such that the wavelength of the laser beam becomes a center wavelength of the target wavelength band.

3. The laser wavelength control device according to claim 2, wherein the processor is configured to
heat or cool the light source so as to adjust the temperature in a second setting range included in the data such that the wavelength of the laser beam becomes the center wavelength of the target wavelength band.

4. The laser wavelength control device according to claim 3, wherein the processor is configured to
control the temperature to be in the second setting range by using a Peltier element.

5. The laser wavelength control device according to claim 1, further comprising:
a light source device that includes the light source and a branch portion,
wherein the light source includes a laser diode that emits the laser beam in a first direction, and
the branch portion extracts a light component of the laser beam emitted from the laser diode in a second direction different from the first direction.

6. The laser wavelength control device according to claim 5, wherein
the light source device further includes a lens barrel, and a lens system that is provided in the lens barrel and guides the laser beam from the laser diode in the first direction, and
the branch portion includes a light path that is provided in the lens barrel and extracts the light component of the laser beam passing through a part of the lens system toward an outside of the lens barrel in the second direction.

7. A laser wavelength control device comprising:
a memory; and
a processor coupled to the memory and configured to:
measure a wavelength of a laser beam based on a light component extracted in a direction different from a direction in which a light source emits the laser beam,
when the measured wavelength of the laser beam is not in a target wavelength band, adjust a voltage to be applied to the light source such that the wavelength of the laser beam falls within the target wavelength band by using data which includes the voltage to be applied to the light source, a temperature of the light source, and the wavelength of the laser beam to be emitted by the light source, and
when the wavelength measured at the adjusted voltage is not in the target wavelength band, adjust the temperature of the light source such that a wavelength of the laser beam at an adjusted voltage falls within the target wavelength band by using the data.

8. The laser wavelength control device according to claim 7, wherein the processor is configured to
adjust the voltage in a first setting range included in the data such that the wavelength of the laser beam becomes a center wavelength of the target wavelength band.

9. The laser wavelength control device according to claim 8, wherein the processor is configured to
heat or cool the light source so as to adjust the temperature in a second setting range included in the data such that the wavelength of the laser beam becomes the center wavelength of the target wavelength band.

10. The laser wavelength control device according to claim 9, wherein the processor is configured to
control the temperature to be in a second setting range by using a Peltier element.

11. The laser wavelength control device according to claim 7, further comprising:
a light source device that includes the light source and a branch portion,
wherein the light source includes a laser diode that emits the laser beam in a first direction, and
the branch portion extracts a light component of the laser beam emitted from the laser diode in a second direction different from the first direction.

12. The laser wavelength control device according to claim 11, wherein
the light source device further includes a lens barrel, and a lens system that is provided in the lens barrel and guides the laser beam from the laser diode in the first direction, and
the branch portion includes a light path that is provided in the lens barrel and extracts the light component of the laser beam passing through a part of the lens system toward an outside of the lens barrel in the second direction.

13. A method for controlling a laser wavelength executed by a computer, the laser wavelength control method comprising:
measuring a wavelength of a laser beam based on a light component extracted in a direction different from a direction in which a light source emits the laser beam;
when the measured wavelength of the laser beam is not in a target wavelength band, adjusting a voltage to be applied to the light source such that the wavelength of the laser beam falls within the target wavelength band by using data which includes the voltage to be applied to the light source, a temperature of the light source, and the wavelength of the laser beam to be emitted by the light source, and
when the wavelength measured at the adjusted voltage is not in the target wavelength band, adjusting the temperature of the light source such that a wavelength of the laser beam at an adjusted voltage falls within the target wavelength band by using the data.
